(19) United States
(12) Patent Application Publication
(10) Pub. No.: US 2002/0024142 A1
(43) Pub. Date: Feb. 28, 2002

(54) Semiconductor device and manufacturing method of the same

(76) Inventor: Mitsuru Sekiguchi, Shiga (JP)

Correspondence Address: NIXON PEABODY, LLP, 8180 GREENSBORO DRIVE, SUITE 800, MCLEAN, VA, 22102, US

(21) Appl. No.: 09/931,190

(22) Filed: Aug. 17, 2001

(30) Foreign Application Priority Data
Aug. 24, 2000 (JP) 2000-253802

(51) Int. Cl. H01L 23/48; H01L 23/52; H01L 29/40

(52) U.S. Cl. 257/758

(57) ABSTRACT

A first conductive film is first deposited on an insulating film on a substrate as a seed layer, wetting layer, adhesive layer or the like. The first conductive film is formed from a first copper alloy having oxidation resistance. A second conductive film is then formed on the first conductive film. The second conductive film is formed from copper or a second copper alloy. Thereafter, the first and second conductive films are integrated into a third conductive film, which will results in a wiring.

### BACKGROUND OF THE INVENTION

The present invention generally relates to a semiconductor device having a copper wiring, and a manufacturing method of the same.

With increase in operation speed of the transistors, the delay due to the CR (capacitance-resistance) components of the wirings has become a matter of concern in the silicon LSIs (large scale integrated circuits) of 0.18-μm generation and the following generations. Therefore, as a wiring material, Al (specific resistance of 3 μΩ·cm) is being increasingly replaced with Cu having a lower resistance (specific resistance of 1.7 μΩ·cm) or a metal primarily consisting of Cu (hereinafter, referred to as a copper alloy). Note that a wiring formed from copper or a copper alloy is herein referred to as a copper wiring.

Hereinafter, a conventional method for manufacturing a semiconductor device will be described with reference to FIGS. 7A to 7E. Herein, the copper wiring manufacturing technology using a TaN film as a barrier metal film is described by way of example.

First, as shown in FIG. 7A, a first wiring 13 of a copper film is embedded in a first insulating film 11 on a semiconductor substrate 10 with a first barrier metal film 12 of a TaN film interposed therebetween. Then, a first silicon nitride film 14, a second insulating film 15, a second silicon nitride film 16 and a third insulating film 17 are sequentially deposited on the semiconductor substrate 10. A via hole 18 reaching the first wiring 13 is then formed through the first silicon nitride film 14, second insulating film 15 and second silicon nitride film 16. A wiring groove 19 reaching the first wiring 13 through the via hole 18 is also formed through the third insulating film 17. The first barrier metal film 12 or the first silicon nitride film 14 prevents the copper atoms of the first wiring 13 from diffusing into the first insulating film 11, the second insulating film 15 or the like due to the thermal processing at about 400° C. for depositing the second insulating film 15, the second silicon nitride film 16 or the like. In other words, the first barrier metal film 12 or the first silicon nitride film 14 serves as a barrier against diffusion of the copper atoms.

Then, as shown in FIG. 7B, a second barrier metal film 20 of a TaN film and a copper seed layer 21 of a copper film are sequentially deposited on the respective bottoms and wall surfaces of the via hole 18 and the wiring groove 19 by using a sputtering method.

The semiconductor substrate 10 is then transferred from the sputtering apparatus into a plating apparatus. At this time, the surface of the semiconductor substrate 10, i.e., the surface of the copper seed layer 21, is exposed to the air. Then, as shown in FIG. 7C, a copper plating film 22 is grown on the copper seed layer 21 by an electroplating method so as to completely fill the via hole 18 and the wiring groove 19.

Thereafter, the copper plating film 22 is thermally processed (e.g., at about 100° C. for about two hours) in order to grow crystal grains of the copper plating film 22. Thus, as shown in FIG. 7D, the copper seed layer 21 and the copper plating film 22 are integrated into a wiring copper film 23.

As shown in FIG. 7E, the second barrier metal film 20 and the wiring copper film 23 located outside the wiring groove 19 are then removed to form a via 24 and a second wiring 25 from the wiring copper film 23. Thus, the first wiring 13 is connected to the second wiring 25 through the via 24.

Although not shown in the figure, a desired multi-layer wiring structure is then formed as necessary by repeatedly conducting the steps of FIGS. 7A to 7E (regarding FIG. 7A, the step of depositing the first silicon nitride film 14 and the following steps).

In the conventional manufacturing method of the semiconductor device, however, the copper seed layer 21 deposited by the sputtering method may have a reduced thickness on the wall surface of the via hole 18 due to the directivity of the sputtering method, as shown in FIG. 8A. Moreover, as described before, the surface of the copper seed layer 21 is exposed to the air during transfer of the semiconductor substrate 10 from the sputtering apparatus into the plating apparatus after deposition of the copper seed layer 21. Therefore, as shown in FIG. 8B, the copper seed layer 21 forms a copper oxide layer 21a at its surface. At this time, the thinner portion of the copper seed layer 21 is entirely oxidized into the copper oxide layer 21a. When the semiconductor substrate 10 is immersed in a plating solution including CuSO₄, H₂SO₄ and the like in order to form the copper plating film 22, the copper oxide layer 21a may possibly be dissolved therein as shown in FIG. 8C. Moreover, the copper oxide layer 21a has poor electric conductivity. Accordingly, the copper seed layer 21 has reduced electric conductivity at the thinner portion, making it impossible to sufficiently grow the copper plating film 22. As shown in FIG. 8D, this may results in filling defects such as voids in the via hole 18 or the like.

In order to fill a recess formed in the insulating film on the substrate with a copper film, a method such as combination of sputtering and reflow methods, or a CVD (chemical vapor deposition) method may be used instead of the electroplating method.

When the combination of sputtering and reflow methods is used instead of the electroplating method, a thin copper film having an excellent coverage is preferably pre-deposited as a wetting layer (hereinafter, referred to as a copper wetting layer) in order to improve the reflow property of a copper film to be deposited by the sputtering method (hereinafter, referred to as a copper sputtering film). However, oxidation of the copper wetting layer would degrade the reflow property of the copper sputtering film due to non-uniform oxidation at the surface of the copper wetting layer, and also degrade adhesion between the copper sputtering film and the barrier metal film after the reflow process, resulting in reduced reliability of the embedded wiring.

When the CVD method is used instead of the electroplating method, a thin copper film having an excellent coverage is preferably pre-deposited as an adhesive layer (hereinafter, referred to as a copper adhesive layer) in order to improve adhesion between a copper film to be deposited by the CVD method (hereinafter, referred to as a copper CVD film) and the barrier metal film. However, oxidation of the copper adhesive layer would degrade the adhesion between the copper CVD film and the barrier metal film, and also degrade uniformity of the deposition of the copper CVD film, resulting in reduced reliability of the embedded wiring.

The reduced reliability of the wiring due to oxidation of the copper seed layer, copper wetting layer, copper adhesive layer or the like is induced even when a copper film formed on the insulating film (which may have a recess therein) by the electroplating method, combination of sputtering and reflow methods, CVD method or the like is patterned into a wiring.

### SUMMARY OF THE INVENTION

In view of the foregoing problems, it is one object of the present invention to enable a conductive film to be formed on a seed layer in a recess by using an electroplating method, while preventing generation of filling defects. It is another object of the present invention to prevent degradation in reliability of a wiring due to oxidation of Cu included in a layer such as a seed layer, wetting layer or adhesive layer.

In order to achieve the aforementioned one or another object, the inventors studied a method for preventing oxidation of Cu included in a seed layer or the like, and found that the use of a copper alloy containing Al, Si, Ir, Ru or the like (hereinafter, referred to as an oxidation-resistant copper alloy) as a material of the seed layer enables prevention of oxidation of Cu included in the seed layer. More specifically, when the oxidation-resistant copper alloy is exposed to the air, a thin oxide layer of Al, Si, Ir or Ru is formed at its surface (P. J. Ding et al., APL 64, p. 2897, 1994), so that Cu of the oxidation-resistant copper alloy located inside the oxide layer can be prevented from being oxidized. Since the oxide layer formed at the surface of the oxidation-resistant copper alloy is extremely thin, the oxidation-resistant copper alloy has less reduced conductivity. In particular, the oxide layer of Ir or Ru is conductive, and therefore hardly affects the conductivity of the oxidation-resistant copper alloy.

The present invention is made based on the foregoing knowledge. More specifically, in order to achieve the aforementioned one or another object, a semiconductor device according to a first aspect of the invention includes: an insulating film formed on a substrate; and an embedded wiring formed in the insulating film, wherein the embedded wiring is formed from a copper alloy containing at least one of elements Al, Si, Ir and Ru, and a content of the element in the embedded wiring is increased toward the insulating film.

According to the semiconductor device of the first aspect of the invention, the embedded wiring is obtained as follows: a first conductive film is first deposited on a bottom and wall surface of a recess formed in the insulating film on the substrate. A second conductive film is then formed on the first conductive film so as to completely fill the recess. Thereafter, the first and second conductive films are integrated into a third conductive film. The first conductive film is formed from a first copper alloy containing at least one of the elements Al, Si, Ir and Ru, and the second conductive film is formed from copper or a second copper alloy. In other words, the first copper alloy containing Al, Si, Ir or Ru, that is, an oxidation-resistant copper alloy, is used as a material of the first conductive film. Therefore, in the case where the second conductive film is formed by an electroplating method using the first conductive film as a seed layer, oxidation of Cu included in the seed layer can be prevented. As a result, the seed layer will not be dissolved in a plating solution, as well as conductivity of the seed layer will not be reduced. Therefore, even when the seed layer has a reduced thickness on the wall surface of the recess or the like, the second conductive film can be formed on the seed layer in the recess by the electroplating method, while preventing generation of filling defects. Moreover, in the case where the second conductive film is formed by combination of sputtering and reflow methods, a CVD method or the like using the first conductive film as a wetting layer, adhesive layer or the like, oxidation of Cu included in the wetting layer, adhesive layer or the like can be prevented. As a result, degradation in reliability of the embedded wiring due to the oxidation of Cu can be prevented.

According to the semiconductor device of the first aspect of the invention, the embedded wiring is formed from an oxidation-resistant copper alloy that is less susceptible to mechanical deformation than pure copper. Therefore, the embedded wiring has improved electro-migration resistance or stress migration resistance.

In order to achieve the aforementioned another object, a semiconductor device according to a second aspect of the invention includes: an insulating film formed on a substrate; and a wiring formed on the insulating film, wherein the wiring is formed from a copper alloy containing at least one of elements Al, Si, Ir and Ru, and a content of the element in the wiring is increased toward the insulating film.

According to the semiconductor device of the second aspect of the invention, the wiring is obtained as follows: a first conductive film is first deposited on the insulating film on the substrate. A second conductive film is then formed on the first conductive film, and the first and second conductive films are integrated into a third conductive film. Thereafter, the third conductive film is etched using a mask pattern covering a wiring formation region. The first conductive film is formed from a first copper alloy containing at least one of the elements Al, Si, Ir and Ru, and the second conductive film is formed from copper or a second copper alloy. In other words, the first copper alloy containing Al, Si, Ir or Ru, that is, an oxidation-resistant copper alloy, is used as a material of the first conductive film. Therefore, in the case where the second conductive film is formed by an electroplating method using the first conductive film as a seed layer, oxidation of Cu included in the seed layer can be prevented. As a result, degradation in reliability of the wiring due to the oxidation of Cu can be prevented. Moreover, in the case where the second conductive film is formed by combination of sputtering and reflow methods, a CVD method or the like using the first conductive film as a wetting layer, adhesive layer or the like, oxidation of Cu included in the wetting layer, adhesive layer or the like can be prevented. As a result, degradation in reliability of the wiring due to the oxidation of Cu can be prevented.

According to the semiconductor device of the second aspect of the invention, the wiring is formed from an oxidation-resistant copper alloy that is less susceptible to mechanical deformation than pure copper. Therefore, the wiring has improved electro-migration resistance or stress migration resistance.

In order to achieve the aforementioned one object, a method for manufacturing a semiconductor device according to a third aspect of the invention includes the steps of: forming a recess in an insulating film on a substrate; depositing a first conductive film on a bottom and wall surface of the recess, the first conductive film being formed from a first copper alloy having oxidation resistance; growing a second conductive film on the first conductive film by an electroplating method so as to completely fill the recess, the second conductive film being formed from copper or a second copper alloy; and integrating the first and second conductive films into a third conductive film so as to form an embedded wiring of the third conductive film.

According to the manufacturing method of the third aspect of the invention, the first conductive film is first deposited on the bottom and wall surface of the recess formed in the insulating film on the substrate. The second conductive film is then grown on the first conductive film by the electroplating method so as to completely fill the recess. Thereafter, the first and second conductive films are integrated into the third conductive film so as to form the embedded wiring of the third conductive film. The first conductive film is formed from the first copper alloy having oxidation resistance. In other words, the first copper alloy having oxidation resistance is used as a material of the first conductive film, i.e., a seed layer, whereby oxidation of Cu included in the seed layer can be prevented. As a result, the seed layer will not be dissolved in a plating solution, as well as conductivity of the seed layer will not be reduced. Therefore, even when the seed layer has a reduced thickness on the wall surface of the recess or the like, the second conductive film can be formed on the seed layer in the recess by the electroplating method, while preventing generation of filling defects.

In the manufacturing method of the third aspect of the invention, the step of depositing the first conductive film preferably includes the step of depositing the first conductive film with (111) orientation with respect to the bottom of the recess.

Thus, the second conductive film on the first conductive film, i.e., on the seed layer, is also more likely to be grown with (111) orientation with respect to the bottom of the recess. Accordingly, the embedded wiring formed from the third conductive film, i.e., from the integrated film of the first and second conductive films, has improved electro-migration resistance.

In order to achieve the aforementioned another object, a method for manufacturing a semiconductor device according to a fourth aspect of the invention includes the steps of: depositing a first conductive film on an insulating film on a substrate, the first conductive film being formed from a first copper alloy having oxidation resistance; growing a second conductive film on the first conductive film by an electroplating method, the second conductive film being formed from copper or a second copper alloy; integrating the first and second conductive films into a third conductive film; and forming a wiring of the third conductive film by etching the third conductive film using a mask pattern covering a wiring formation region.

According to the manufacturing method of the fourth aspect of the invention, the first conductive film is first deposited on the insulating film on the substrate. The second conductive film is then grown on the first conductive film by the electroplating method. Thereafter, the first and second conductive films are integrated into the third conductive film, so that the wiring is formed by etching the third conductive film. The first conductive film is formed from the first copper alloy having oxidation resistance. In other words, the copper alloy having oxidation resistance is used as a material of the first conductive film, i.e., a seed layer, whereby oxidation of Cu included in the seed layer can be prevented. As a result, degradation in reliability of the wiring due to the oxidation of Cu can be prevented.

In the manufacturing method of the fourth aspect of the invention, the step of depositing the first conductive film preferably includes the step of depositing the first conductive film with (111) orientation with respect to a top surface of the insulating film.

Thus, the second conductive film on the first conductive film, i.e., on the seed layer, is also more likely to be grown with (111) orientation with respect to the top surface of the insulating film. Accordingly, the wiring formed from the third conductive film, i.e., from the integrated film of the first and second conductive films, has improved electro-migration resistance.

In order to achieve the aforementioned another object, a method for manufacturing a semiconductor device according to a fifth aspect of the invention includes the steps of: forming a recess in an insulating film on a substrate; depositing a first conductive film on a bottom and wall surface of the recess, the first conductive film being formed from a first copper alloy having oxidation resistance; forming a second conductive film on the first conductive film so as to completely fill the recess, the second conductive film being formed from copper or a second copper alloy; and integrating the first and second conductive films into a third conductive film so as to form an embedded wiring of the third conductive film.

According to the manufacturing method of the fifth aspect of the invention, the first conductive film is first deposited on the bottom and wall surface of the recess formed in the insulating film on the substrate. The second conductive film is then formed on the first conductive film so as to completely fill the recess. Thereafter, the first and second conductive films are integrated into the third conductive film so as to form the embedded wiring of the third conductive film. The first conductive film is formed from the first copper alloy having oxidation resistance. In other words, the first copper alloy having oxidation resistance is used as a material of the first conductive film. Therefore, in the case where the second conductive film is formed by combination of sputtering and reflow methods, a CVD method or the like using the first conductive film as a wetting layer, adhesive layer or the like, oxidation of Cu included in the wetting layer, adhesive layer or the like can be prevented. As a result, degradation in reliability of the embedded wiring due to the oxidation of Cu can be prevented.

In order to achieve the aforementioned another object, a method for manufacturing a semiconductor device according to a sixth aspect of the invention includes the steps of: depositing a first conductive film on an insulating film on a substrate, the first conductive film being formed from a first copper alloy having oxidation resistance; forming a second conductive film on the first conductive film, the second conductive film being formed from copper or a second copper alloy; integrating the first and second conductive films into a third conductive film; and forming a wiring of the third conductive film by etching the third conductive film using a mask pattern covering a wiring formation region.

According to the manufacturing method of the sixth aspect of the invention, the first conductive film is first deposited on the insulating film on the substrate. The second conductive film is then formed on the first conductive film. Thereafter, the first and second conductive films are integrated into the third conductive film, so that the wiring is formed by etching the third conductive film. The first conductive film is formed from the first copper alloy having oxidation resistance. In other words, the first copper alloy having oxidation resistance is used as a material of the first conductive film. Therefore, in the case where the second conductive film is formed by combination of sputtering and reflow methods, a CVD method or the like using the first conductive film as a wetting layer, adhesive layer or the like, oxidation of Cu included in the wetting layer, adhesive layer or the like can be prevented. As a result, degradation in reliability of the wiring due to the oxidation of Cu can be prevented.

In the manufacturing method of the fifth or sixth aspect of the invention, the step of forming the second conductive film preferably includes the step of causing the second conductive film to flow by a thermal processing after deposition of the second conductive film by a sputtering method.

This enables the second conductive film to sufficiently flow, thereby improving the reliability of the wiring.

In the manufacturing method of the fifth or sixth aspect of the invention, the step of forming the second conductive film preferably includes the step of depositing the second conductive film by a CVD method.

This enables uniform deposition of the second conductive film, thereby improving the reliability of the wiring.

In the manufacturing method of the third, fourth, fifth or sixth aspect of the invention, the first copper alloy preferably contains at least one of elements Al, Si, Ir and Ru.

Thus, oxidation of Cu included in the first conductive film can be reliably prevented. Moreover, the third conductive film, which results in the wiring, is formed from the copper alloy containing at least one of the elements Al, Si, Ir and Ru, i.e., an oxidation-resistant copper alloy that is less susceptible to mechanical deformation than pure copper. Therefore, the wiring has improved electro-migration resistance or stress migration resistance.

### BRIEF DESCRIPTION OF THE DRAWINGS

FIGS. 1A to 1E are cross-sectional views illustrating the steps of a method for manufacturing a semiconductor device according to a first embodiment of the present invention;

FIGS. 2A to 2E are cross-sectional views illustrating the steps of a method for manufacturing a semiconductor device according to a second embodiment of the present invention;

FIGS. 3A to 3E are cross-sectional views illustrating the steps of a method for manufacturing a semiconductor device according to a third embodiment of the present invention;

FIGS. 4A to 4E are cross-sectional views illustrating the steps of a method for manufacturing a semiconductor device according to a fourth embodiment of the present invention;

FIGS. 5A to 5E are cross-sectional views illustrating the steps of a method for manufacturing a semiconductor device according to a fifth embodiment of the present invention;

FIGS. 6A to 6D are cross-sectional views illustrating the steps of a method for manufacturing a semiconductor device according to the fifth embodiment of the present invention;

FIGS. 7A to 7E are cross-sectional views illustrating the steps of a conventional method for manufacturing a semiconductor device; and

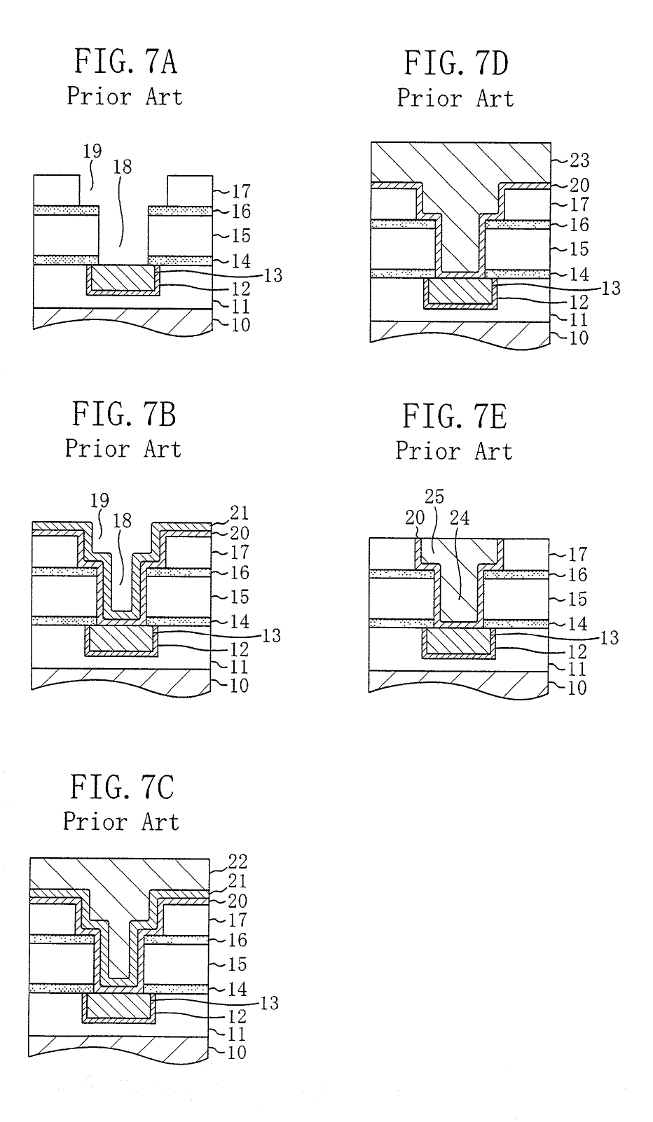

FIGS. 8A to 8D are diagrams illustrating the problems in the conventional method for manufacturing a semiconductor device.

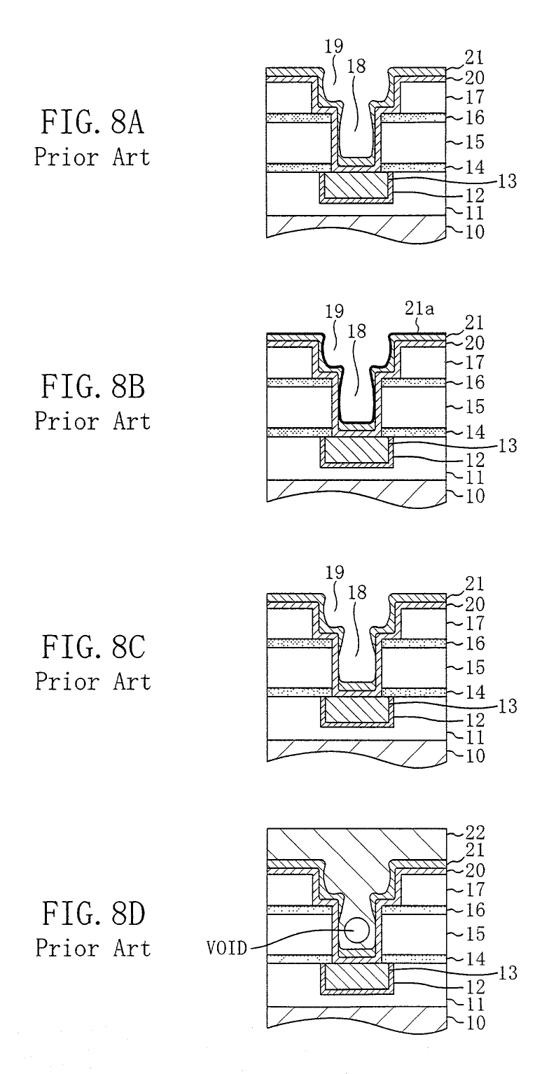

### DETAILED DESCRIPTION OF THE INVENTION

(First Embodiment)

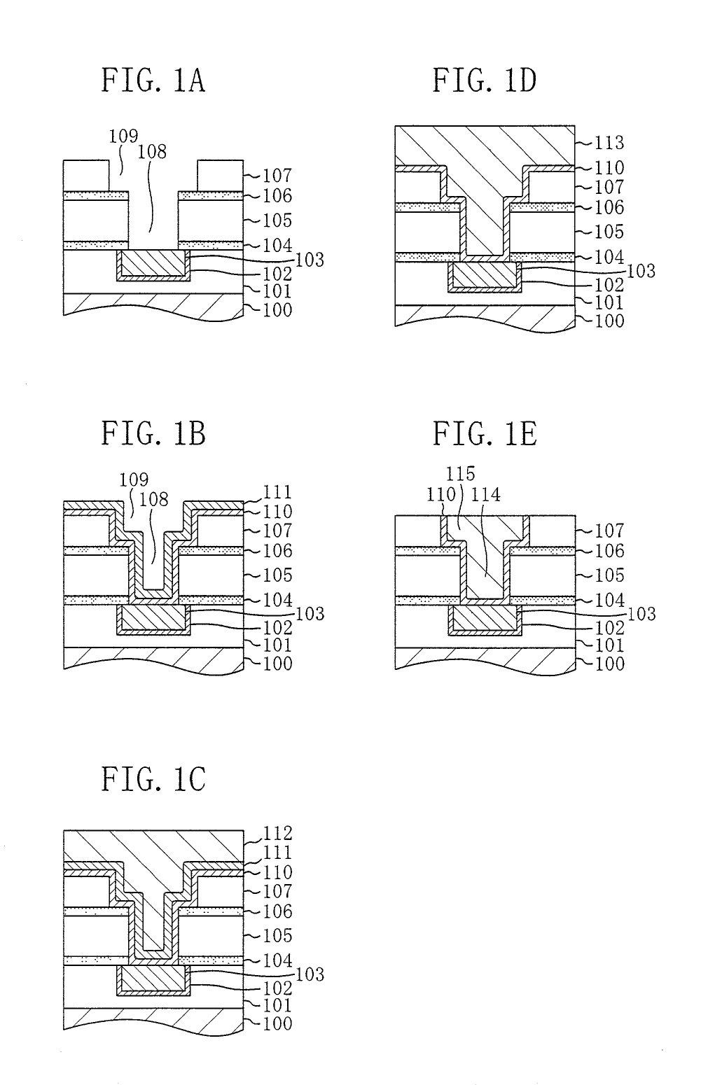

Hereinafter, a semiconductor device and a manufacturing method thereof according to the first embodiment of the present invention will be described with reference to FIGS. 1A to 1E.

First, as shown in FIG. 1A, a first wiring 103 of, e.g., a copper film is embedded in a first insulating film 101 on a semiconductor substrate 100 with a first barrier metal film 102 of, e.g., a TaN film interposed therebetween. Then, a first silicon nitride film 104, a second insulating film 105, a second silicon nitride film 106 and a third insulating film 107 are sequentially deposited on the semiconductor substrate 100. A via hole 108 reaching the first wiring 103 is then formed through the first silicon nitride film 104, second insulating film 105 and second silicon nitride film 106. The via hole 108 has a depth of about 500 nm. A wiring groove 109 reaching the first wiring 103 through the via hole 108 is also formed through the third insulating film 107. The wiring groove 109 has a depth of about 300 nm. The first barrier metal film 102 or the first silicon nitride film 104 prevents the copper atoms of the first wiring 103 from diffusing into the first insulating film 101, the second insulating film 105 or the like due to the thermal processing at about 400° C. (e.g., plasma CVD method) for depositing the second insulating film 105, the second silicon nitride film 106 or the like. In other words, the first barrier metal film 102 or the first silicon nitride film 104 serves as a barrier against diffusion of the copper atoms.

As shown in FIG. 1B, a second barrier metal film 110 of, e.g., a TaN film is then deposited on the semiconductor substrate 100 by, e.g., a sputtering method. The second barrier metal film 110 has a thickness of, e.g., 25 nm. Thereafter, a copper alloy seed layer 111 having a thickness of 150 nm is deposited on the second barrier metal film 110 by, e.g., a sputtering method using a copper alloy target of Cu—1% by mass of Al. Thus, the respective bottoms and wall surfaces of the via hole 108 and the wiring groove 109 are covered with the second barrier metal film 110 and the copper alloy seed layer 111. Note that the copper alloy seed layer 111 contains about 1% by mass of Al.

The semiconductor substrate 100 is then transferred from the sputtering apparatus into a plating apparatus. At this time, the copper alloy seed layer 111 is exposed to the air. Since the copper alloy seed layer 111 forms an extremely thin (about several nanometers) aluminum oxide layer (A1₂O₃ film) at its surface, Cu included in the copper alloy seed layer 111 will not be oxidized.

Then, as shown in FIG. 1C, a copper plating film 112 having a thickness of 350 nm is grown on the copper alloy seed layer 111 by an electroplating method so as to completely fill the via hole 108 and the wiring groove 109. More specifically, with the semiconductor substrate 100 being immersed in a plating solution including CuSO₄, H₂SO₄ and the like, the electroplating method is conducted such that the semiconductor substrate 100 has a negative potential. Since Cu included in the copper alloy seed layer 111 is not oxidized, the copper alloy seed layer 111 will not be dissolved in the plating solution as well as the conductivity of the copper alloy seed layer 111 will not be reduced. Thus, the via hole 108 and the wiring groove 109 can be reliably filled with the copper plating film 112.

Thereafter, the semiconductor substrate 100 is removed from the plating apparatus, and the copper plating film 112 is thermally processed at, e.g., about 100° C. to about 400° C. in order to grow crystal grains of the copper plating film 112. As a result, the aluminum atoms included in the copper alloy seed layer 111 are diffused into the copper plating film 112, so that the copper alloy seed layer 111 and the copper plating film 112 are integrated into a wiring copper alloy film 113 containing about 0.3% by mass of aluminum, as shown in FIG. 1D. Note that, instead of thermally processing the copper plating film 112, the semiconductor substrate 100 may be left at room temperature for about two days. Alternatively, an additional step involving temperature rise (about 100° C. to about 400° C.) may be conducted between the step of forming the copper plating film 112 and the step of removing the wiring copper alloy film 113 located outside the wiring groove 109 (see FIG. 1E). In such a case, the aforementioned thermal processing may be omitted.

As shown in FIG. 1E, by using, e.g., a CMP (chemical mechanical polishing) method, the second barrier metal film 110 and the wiring copper alloy film 113 located outside the wiring groove 109 are then removed to form a via 114 and a second wiring 115 from the wiring copper alloy film 113. Thus, the first wiring 103 is connected to the second wiring 115 through the via 114.

Note that the copper alloy seed layer 111 and the copper plating film 112 are integrated into the wiring copper alloy film 113 as a result of diffusion of the aluminum atoms in the copper alloy seed layer 111 into the copper plating film 112. Therefore, the aluminum content in the via 114 and the second wiring 115 is increased toward the second barrier metal film 110, that is, toward the first silicon nitride film 104, second insulating film 105, second silicon nitride film 106, third insulating film 107 or first wiring 103.

Although not shown in the figure, a desired multi-layer wiring structure is then formed as necessary by repeatedly conducting the steps of FIGS. 1A to 1E (regarding FIG. 1A, the step of depositing the first silicon nitride film 104 and the following steps).

As has been described above, according to the first embodiment, the copper alloy seed layer 111 of an Al-containing copper alloy is deposited on the respective bottoms and wall surfaces of the via hole 108 and the wiring groove 109. Thereafter, by using an electroplating method, the copper plating film 112 is grown on the copper alloy seed layer 111 so as to completely fill the via hole 108 and the wiring groove 109. Then, the copper alloy seed layer 111 and the copper plating film 112 are integrated into the wiring copper alloy film 113, so that the via 114 and the second wiring 115 are formed from the wiring copper alloy film 113. In other words, an Al-containing copper alloy, i.e., an oxidation-resistant copper alloy, is used as a material of the copper alloy seed layer 111, whereby oxidation of Cu included in the copper alloy seed layer 111 can be prevented. As a result, the copper alloy seed layer 111 will not be dissolved in a plating solution, as well as the conductivity of the copper alloy seed layer 111 will not be reduced. Therefore, even when the copper alloy seed layer 111 has a reduced thickness on the wall surface of the via hole 108 or the like, the copper plating film 112 can be formed on the copper alloy seed layer 111 in the via hole 108 or the wiring groove 109 by using an electroplating method, while preventing generation of filling defects. As a result, a margin of filling the via hole 108 or the wiring groove 109 with the copper plating film 112 is increased.

Moreover, according to the first embodiment, the wiring copper alloy film 113 that will result in the via 114 and the second wiring 115 is formed from an Al-containing copper alloy, that is, an oxidation-resistant copper alloy that is less susceptible to mechanical deformation than pure copper. Therefore, the via 114 and the second wiring 115 have improved electro-migration resistance or stress migration resistance.

Note that, in the first embodiment, an Al-containing copper alloy is used as a material of the copper alloy seed layer 111. However, the present invention is not limited to this, and it is preferable to use a copper alloy containing at least one of the elements Al, Si, Ir and Ru. Although Cu—1% by mass of Al is used as the Al-containing copper alloy, the Al content in the copper alloy is not specifically limited.

In the first embodiment, pure copper is used as a material of the first wiring 103 or the copper plating film 112. However, a copper alloy may alternatively be used.

In the first embodiment, a TaN film is used as the first barrier metal film 102 or the second barrier metal film 110. However, a Ta film, Ti film, TiN film or the like may alternatively be used.

In the first embodiment, an SiO₂ film, an SOG (Spin On Glass) film, a CVD film including C and having a low dielectric constant, or the like may be used as the first insulating film 101, second insulating film 105 or third insulating film 107.

A dual damascene method in which the via hole 108 and the wiring groove 109 are simultaneously filled with a conductive film is used in the first embodiment. Alternatively, the via hole 108 and the wiring groove 109 may be separately formed and separately filled with a conductive film.

(Modification of First Embodiment)

Hereinafter, a method for manufacturing a semiconductor device according to a modification of the first embodiment will be described.

The modification of the first embodiment is different from the first embodiment in that the copper alloy seed layer 111 is deposited with (111) orientation with respect to the bottom of the via hole 108 or the wiring groove 109 in the step of depositing the copper alloy seed layer 111 (see FIG. 1B). It is preferable that, by using, e.g., a highly directional sputtering method, the copper alloy seed layer 111 is deposited with a larger thickness on the bottom of the via hole 108 or the wiring groove 109 than on the wall surface thereof, and that the copper alloy seed layer 111 is not deposited with (111) orientation with respect to the wall surface of the via hole 108 or the wiring groove 109.

According to the modification of the first embodiment, the following effects are obtained in addition to the effects of the first embodiment. Since the copper alloy seed layer 111 is deposited with (111) orientation with respect to the bottom of the via hole 108 or the wiring groove 109, the copper plating film 112 on the copper alloy seed layer 111 is also more likely to be grown with (111) orientation with respect to the bottom of the via hole 108 or the wiring groove 109. In general, the electro-migration resistance of a copper film or a copper alloy film is improved as the (111) orientation of the copper film or the copper alloy film is increased (C. Ryu et al., Proc. IRPS., p. 201, 1997). Accordingly, the via 114 or the second wiring 115 formed from the wiring copper alloy film 113, i.e., from the integrated film of the copper alloy seed layer 111 and the copper plating film 112, has improved electro-migration resistance.

Note that, in the modification of the first embodiment, it is preferable to improve the (111) orientation of the copper alloy seed layer 111 by, e.g., a thermal processing after deposition of the copper alloy seed layer 111. This also improves the (111) orientation of the copper plating film 112, so that the via 114 or the second wiring 115 has further improved electro-migration resistance.

(Second Embodiment)

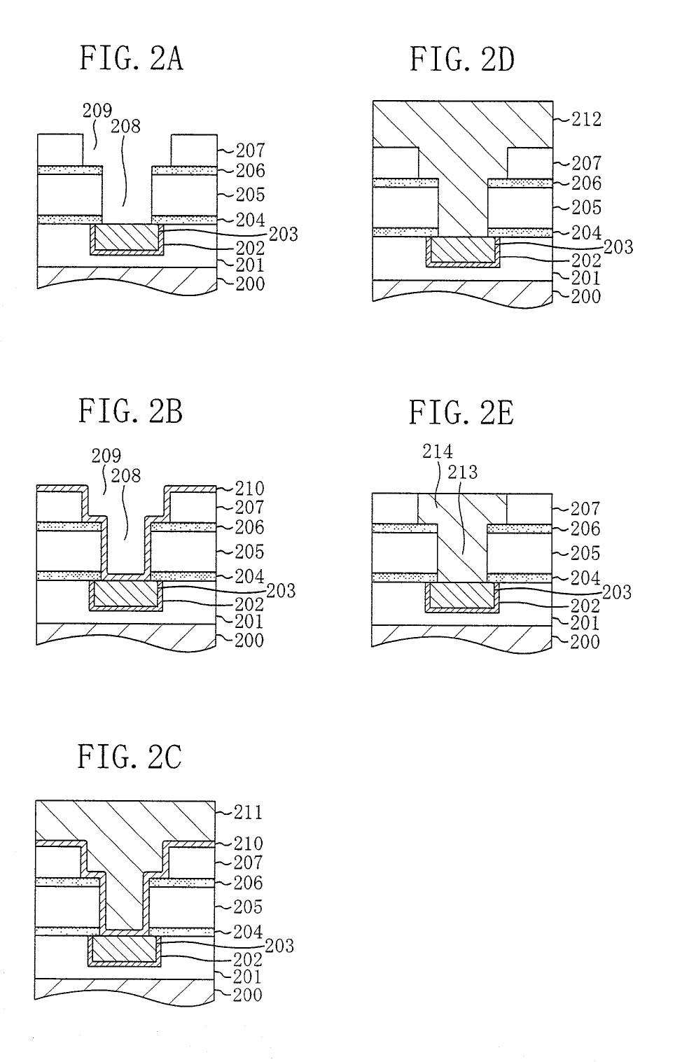

Hereinafter, a semiconductor device and a manufacturing method thereof according to the second embodiment of the present invention will be described with reference to FIGS. 2A to 2E.

First, like the step of FIG. 1A in the first embodiment, as shown in FIG. 2A, a first wiring 203 of, e.g., a copper film is embedded in a first insulating film 201 on a semiconductor substrate 200 with a barrier metal film 202 of, e.g., a TaN film interposed therebetween. Then, a first silicon nitride film 204, a second insulating film 205, a second silicon nitride film 206 and a third insulating film 207 are sequentially deposited on the semiconductor substrate 200. A via hole 208 reaching the first wiring 203 is then formed through the first silicon nitride film 204, second insulating film 205 and second silicon nitride film 206. The via hole 208 has a depth of about 500 nm. A wiring groove 209 reaching the first wiring 203 through the via hole 208 is also formed through the third insulating film 207. The wiring groove 209 has a depth of about 300 nm. The barrier metal film 202 or the first silicon nitride film 204 prevents the copper atoms of the first wiring 203 from diffusing into the first insulating film 201, the second insulating film 205 or the like due to the thermal processing at about 400° C. (e.g., plasma CVD method) for depositing the second insulating film 205, the second silicon nitride film 206 or the like. In other words, the barrier metal film 202 or the first silicon nitride film 204 serves as a barrier against diffusion of the copper atoms.

As shown in FIG. 2B, a copper alloy seed layer 210 having a thickness of 150 nm is deposited on the semiconductor substrate 200 by, e.g., a sputtering method using a copper alloy target of Cu—1% by mass of Al. Thus, the respective bottoms and wall surfaces of the via hole 208 and the wiring groove 209 are covered with the copper alloy seed layer 210. Note that the copper alloy seed layer 210 contains about 1% by mass of Al.

The second embodiment is different from the first embodiment in that the copper alloy seed layer 111 is deposited after deposition of the second barrier metal film 110 in the first embodiment, but the copper alloy seed layer 210 is deposited without deposition of the barrier metal film in the second embodiment. The copper alloy seed layer 210 forms an aluminum oxide layer (Al₂O₃ film) at the boundary with the second insulating film 205, the third insulating film 207 or the like. This aluminum oxide layer serves as a barrier against diffusion of the copper atoms.

The semiconductor substrate 200 is then transferred from the sputtering apparatus into a plating apparatus. At this time, the copper alloy seed layer 210 is exposed to the air. Since the copper alloy seed layer 210 forms an extremely thin (about several nanometers) aluminum oxide layer (Al₂O₃ film) at its surface, Cu included in the copper alloy seed layer 210 will not be oxidized.

Then, as shown in FIG. 2C, a copper plating film 211 having a thickness of 350 nm is grown on the copper alloy seed layer 210 by an electroplating method so as to completely fill the via hole 208 and the wiring groove 209. More specifically, with the semiconductor substrate 200 being immersed in a plating solution including CuSO₄, H₂SO₄ and the like, the electroplating method is conducted such that the semiconductor substrate 200 has a negative potential. Since Cu included in the copper alloy seed layer 210 is not oxidized, the copper alloy seed layer 210 will not be dissolved in the plating solution as well as the conductivity of the copper alloy seed layer 210 will not be reduced. Thus, the via hole 208 and the wiring groove 209 can be reliably filled with the copper plating film 211.

Thereafter, the semiconductor substrate 200 is removed from the plating apparatus, and the copper plating film 211 is thermally processed at, e.g., about 100° C. to about 400° C. in order to grow crystal grains of the copper plating film 211. As a result, the aluminum atoms included in the copper alloy seed layer 210 are diffused into the copper plating film 211, so that the copper alloy seed layer 210 and the copper plating film 211 are integrated into a wiring copper alloy film 212 containing about 0.3% by mass of aluminum, as shown in FIG. 2D. Note that, instead of thermally processing the copper plating film 211, the semiconductor substrate 200 may be left at room temperature for about two days. Alternatively, an additional step involving temperature rise (about 100° C. to about 400° C.) may be conducted between the step of forming the copper plating film 211 and the step of removing the wiring copper alloy film 212 located outside the wiring groove 209 (see FIG. 2E). In such a case, the aforementioned thermal processing may be omitted.

As shown in FIG. 2E, by using, e.g., a CMP method, the wiring copper alloy film 212 located outside the wiring groove 209 is then removed to form a via 213 and a second wiring 214 from the wiring copper alloy film 212. Thus, the first wiring 203 is connected to the second wiring 214 through the via 213.

Note that the copper alloy seed layer 210 and the copper plating film 211 are integrated into the wiring copper alloy film 212 as a result of diffusion of the aluminum atoms in the copper alloy seed layer 210 into the copper plating film 211. Therefore, the aluminum content in the via 213 and the second wiring 214 is increased toward the first silicon nitride film 204, second insulating film 205, second silicon nitride film 206, third insulating film 207 or first wiring 203.

Although not shown in the figure, a desired multi-layer wiring structure is then formed as necessary by repeatedly conducting the steps of FIGS. 2A to 2E (regarding FIG. 2A, the step of depositing the first silicon nitride film 204 and the following steps).

As has been described above, according to the second embodiment, the copper alloy seed layer 210 of an Al-containing copper alloy is deposited on the respective bottoms and wall surfaces of the via hole 208 and the wiring groove 209. Thereafter, by using an electroplating method, the copper plating film 211 is grown on the copper alloy seed layer 210 so as to completely fill the via hole 208 and the wiring groove 209. Then, the copper alloy seed layer 210 and the copper plating film 211 are integrated into the wiring copper alloy film 212, so that the via 213 and the second wiring 214 are formed from the wiring copper alloy film 212. In other words, an Al-containing copper alloy, i.e., an oxidation-resistant copper alloy, is used as a material of the copper alloy seed layer 210, whereby oxidation of Cu included in the copper alloy seed layer 210 can be prevented. As a result, the copper alloy seed layer 210 will not be dissolved in a plating solution, as well as the conductivity of the copper alloy seed layer 210 will not be reduced. Therefore, even when the copper alloy seed layer 210 has a reduced thickness on the wall surface of the via hole 208 or the like, the copper plating film 211 can be formed on the copper alloy seed layer 210 in the via hole 208 or the wiring groove 209 by using an electroplating method, while preventing generation of filling defects. As a result, a margin of filling the via hole 208 or the wiring groove 209 with the copper plating film 211 is increased.

Moreover, according to the second embodiment, the wiring copper alloy film 212 that will result in the via 213 and the second wiring 214 is formed from an Al-containing copper alloy, that is, an oxidation-resistant copper alloy that is less susceptible to mechanical deformation than pure copper. Therefore, the via 213 and the second wiring 214 have improved electro-migration resistance or stress migration resistance.

Moreover, according to the second embodiment, the copper alloy seed layer 210 is deposited on the respective bottoms and wall surfaces of the via hole 208 and the wiring groove 209 without interposing any barrier metal film therebetween. The copper alloy seed layer 210 forms an aluminum oxide layer (Al₂O₃ film) at the boundary with the second insulating film 205, the third insulating film 207 or the like through which the via hole 208 and the wiring groove 209 are formed. This aluminum oxide layer serves as a barrier against diffusion of the copper atoms. This enables the step of forming the via 213 or the second wiring 214 to be simplified while preventing diffusion of the copper atoms of the via 213 or the second wiring 214. Moreover, the via 213 and the second wiring 214 can be formed from the wiring copper alloy film 212, i.e., the integrated film of the copper alloy seed layer 210 and the copper plating film 211, so as to completely fill the via hole 208 and the wiring groove 209. In other words, no barrier metal film having a higher resistance than the wiring copper alloy film 212 is formed on the respective bottoms and wall surfaces of the via hole 208 and the wiring groove 209. Therefore, the respective resistances of the via 213 and the second wiring 214 are reduced.

Note that, in the second embodiment, an Al-containing copper alloy is used as a material of the copper alloy seed layer 210. However, the present invention is not limited to this, and it is preferable to use a copper alloy containing at least one of the elements Al, Si, Ir and Ru. Although Cu—1% by mass of Al is used as the Al-containing copper alloy, the Al content in the copper alloy is not specifically limited.

In the second embodiment, pure copper is used as a material of the first wiring 203 or the copper plating film 211. However, a copper alloy may alternatively be used.

In the second embodiment, a TaN film is used as the barrier metal film 202. However, a Ta film, Ti film, TiN film or the like may alternatively be used.

In the second embodiment, an SiO₂ film, an SOG film, a CVD film including C and having a low dielectric constant, or the like may be used as the first insulating film 201, second insulating film 205 or third insulating film 207.

A dual damascene method in which the via hole 208 and the wiring groove 209 are simultaneously filled with a conductive film is used in the second embodiment. Alternatively, the via hole 208 and the wiring groove 209 may be separately formed and separately filled with a conductive film.

In the second embodiment, it is preferable to deposit the copper alloy seed layer 210 with (111) orientation with respect to the bottom of the via hole 208 or the wiring groove 209 in the step of depositing the copper alloy seed layer 210 (see FIG. 2B). As a result, the copper plating film 211 on the copper alloy seed layer 210 is also more likely to be grown with (111) orientation with respect to the bottom of the via hole 208 or the wiring groove 209. Accordingly, the via 213 or the second wiring 214 formed from the wiring copper alloy film 212, i.e., from the integrated film of the copper alloy seed layer 210 and the copper plating film 211, has improved electro-migration resistance.

In the second embodiment, it is preferable to improve the (111) orientation of the copper alloy seed layer 210 by, e.g., a thermal processing after deposition of the copper alloy seed layer 210. This also improves the (111) orientation of the copper plating film 211, so that the via 213 or the second wiring 214 has further improved electro-migration resistance.

In the second embodiment, it is preferable to nitride the surface of the second insulating film 205 or the surface of the third insulating film 207 before deposition of the copper alloy seed layer 210 by exposing the semiconductor substrate 200 to nitrogen plasma or ammonia plasma. This causes the nitrided portion of the second insulating film 205 or the nitrided portion of the third insulating film 207 to serve as a barrier against diffusion of the copper atoms. Accordingly, diffusion of the copper atoms of the via 213 or the second wiring 214 can be prevented in a more reliable manner.

(Third Embodiment)

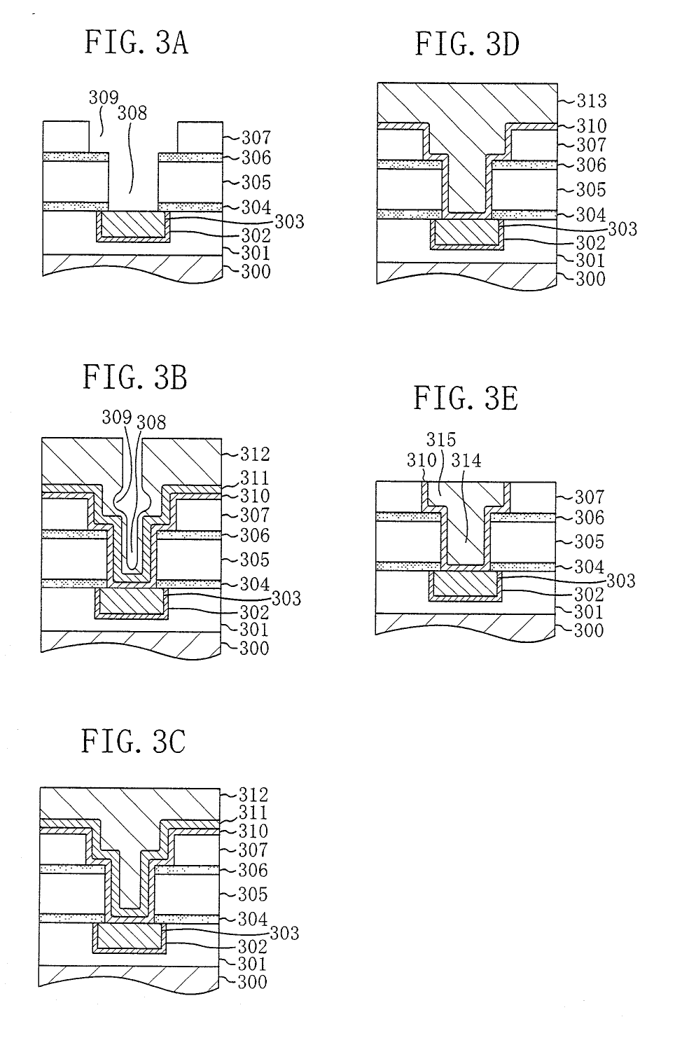

Hereinafter, a semiconductor device and a manufacturing method thereof according to the third embodiment of the present invention will be described with reference to FIGS. 3A to 3E.

First, like the step of FIG. 1A in the first embodiment, as shown in FIG. 3A, a first wiring 303 of, e.g., a copper film is embedded in a first insulating film 301 on a semiconductor substrate 300 with a first barrier metal film 302 of, e.g., a TaN film interposed therebetween. Then, a first silicon nitride film 304, a second insulating film 305, a second silicon nitride film 306 and a third insulating film 307 are sequentially deposited on the semiconductor substrate 300. A via hole 308 reaching the first wiring 303 is then formed through the first silicon nitride film 304, second insulating film 305 and second silicon nitride film 306. The via hole 308 has a depth of about 500 nm. A wiring groove 309 reaching the first wiring 303 through the via hole 308 is also formed through the third insulating film 307. The wiring groove 309 has a depth of about 300 nm. The first barrier metal film 302 or the first silicon nitride film 304 prevents the copper atoms of the first wiring 303 from diffusing into the first insulating film 301, the second insulating film 305 or the like due to the thermal processing at about 400° C. (e.g., plasma CVD method) for depositing the second insulating film 305, the second silicon nitride film 306 or the like. In other words, the first barrier metal film 302 or the first silicon nitride film 304 serves as a barrier against diffusion of the copper atoms.

As shown in FIG. 3B, a second barrier metal film 310 of, e.g., a TaN film is then deposited on the semiconductor substrate 300 by, e.g., a sputtering method. The second barrier metal film 310 has a thickness of, e.g., 25 nm. Thereafter, a copper alloy wetting layer 311 having a thickness of 150 nm is deposited on the second barrier metal film 310 by, e.g., a sputtering method using a copper alloy target of Cu—1% by mass of Al. Thus, the respective bottoms and wall surfaces of the via hole 308 and the wiring groove 309 are covered with the second barrier metal film 310 and the copper alloy wetting layer 311. Note that the copper alloy wetting layer 311 contains about 1% by mass of Al.

Thereafter, a copper sputtering film 312 having a thickness of 600 nm is deposited on the copper alloy wetting layer 311 by using, e.g., a sputtering method. At this time, the via hole 308 or the wiring groove 309 cannot completely be filled with the copper sputtering film 312 due to the directivity of the sputtering method, as shown in FIG. 3B.

As shown in FIG. 3C, the copper sputtering film 312 is then repeatedly oxidized and reduced in an oxidative-reducing atmosphere by using, e.g., an oxidation-reduction reflow method (Proc. of the 42nd Annual Meeting of JSAP (Spring, 1995), p. 810, Cu Wiring Technology (1)—Reduced-Temperature Cu Reflow with Redox Cycle Reaction—). The resultant reaction heat causes the copper sputtering film 312 to flow, thereby completely filling the via hole 308 or the wiring groove 309. Note that, upon oxidizing the copper sputtering film 312, the copper alloy wetting layer 311 is also oxidized simultaneously. However, since the copper alloy wetting layer 311 forms an extremely thin (about several nanometers) aluminum oxide layer (Al₂O₃ film) at its surface, Cu included in the copper alloy wetting layer 311 will not be oxidized. As a result, degradation in the reflow property of the copper sputtering film 312 on the copper alloy wetting layer 311 can be prevented.

Thereafter, the copper sputtering film 312 is thermally processed at, e.g., about 100° C. to about 400° C. in order to grow crystal grains of the copper sputtering film 312. As a result, the aluminum atoms included in the copper alloy wetting layer 311 are diffused into the copper sputtering film 312, so that the copper alloy wetting layer 311 and the copper sputtering film 312 are integrated into a wiring copper alloy film 313 containing about 0.3% by mass of aluminum, as shown in FIG. 3D. Note that, instead of thermally processing the copper sputtering film 312, the semiconductor substrate 300 may be left at room temperature for about two days. Alternatively, an additional step involving temperature rise (about 100° C. to about 400° C.) may be conducted between the step of forming the copper sputtering film 312 and the step of removing the wiring copper alloy film 313 located outside the wiring groove 309 (see FIG. 3E). In such a case, the aforementioned thermal processing may be omitted.

As shown in FIG. 3E, by using, e.g., a CMP method, the second barrier metal film 310 and the wiring copper alloy film 313 located outside the wiring groove 309 are then removed to form a via 314 and a second wiring 315 from the wiring copper alloy film 313. Thus, the first wiring 303 is connected to the second wiring 315 through the via 314.

Note that the copper alloy wetting layer 311 and the copper sputtering film 312 are integrated into the wiring copper alloy film 313 as a result of diffusion of the aluminum atoms in the copper alloy wetting layer 311 into the copper sputtering film 312. Therefore, the aluminum content in the via 314 and the second wiring 315 is increased toward the second barrier metal film 310, that is, toward the first silicon nitride film 304, second insulating film 305, second silicon nitride film 306, third insulating film 307 or first wiring 303.

Although not shown in the figure, a desired multi-layer wiring structure is then formed as necessary by repeatedly conducting the steps of FIGS. 3A to 3E (regarding FIG. 3A, the step of depositing the first silicon nitride film 304 and the following steps).

As has been described above, according to the third embodiment, the copper alloy wetting layer 311 of an Al-containing copper alloy is deposited on the respective bottoms and wall surfaces of the via hole 308 and the wiring groove 309. Thereafter, by using the sputtering and reflow methods, the copper sputtering film 312 is formed on the copper alloy wetting layer 311 so as to completely fill the via hole 308 and the wiring groove 309. Then, the copper alloy wetting layer 311 and the copper sputtering film 312 are integrated into the wiring copper alloy film 313, so that the via 314 and the second wiring 315 are formed from the wiring copper alloy film 313. In other words, an Al-containing copper alloy, i.e., an oxidation-resistant copper alloy, is used as a material of the copper alloy wetting layer 311, whereby oxidation of Cu included in the copper alloy wetting layer 311 can be prevented. As a result, degradation in reliability of the via 314 and the second wiring 315 due to the oxidation of Cu can be prevented.

Moreover, according to the third embodiment, the wiring copper alloy film 313 that will result in the via 314 and the second wiring 315 is formed from an Al-containing copper alloy, that is, an oxidation-resistant copper alloy that is less susceptible to mechanical deformation than pure copper. Therefore, the via 314 and the second wiring 315 have improved electro-migration resistance or stress migration resistance.

Note that, in the third embodiment, an Al-containing copper alloy is used as a material of the copper alloy wetting layer 311. However, the present invention is not limited to this, and it is preferable to use a copper alloy containing at least one of the elements Al, Si, Ir and Ru. Although Cu—1% by mass of Al is used as the Al-containing copper alloy, the Al content in the copper alloy is not specifically limited.

In the third embodiment, pure copper is used as a material of the first wiring 303 or the copper sputtering film 312. However, a copper alloy may alternatively be used.

In the third embodiment, a TaN film is used as the first barrier metal film 302 or the second barrier metal film 310. However, a Ta film, Ti film, TiN film or the like may alternatively be used.

In the third embodiment, an SiO₂ film, an SOG film, a CVD film including C and having a low dielectric constant, or the like may be used as the first insulating film 301, second insulating film 305 or third insulating film 307.

A dual damascene method in which the via hole 308 and the wiring groove 309 are simultaneously filled with a conductive film is used in the third embodiment. Alternatively, the via hole 308 and the wiring groove 309 may be separately formed and separately filled with a conductive film.

In the third embodiment, the copper alloy wetting layer 311 is deposited after deposition of the second barrier metal film 310. However, the copper alloy wetting layer 311 may alternatively be deposited without deposition of the second barrier metal film 310. In this case, it is preferable to nitride the surface of the second insulating film 305 or the surface of the third insulating film 307 before deposition of the copper alloy wetting layer 311 by exposing the semiconductor substrate 300 to nitrogen plasma or ammonia plasma.

In the third embodiment, the combination of sputtering and reflow methods is used to fill the via hole 308 or the wiring groove 309 with the copper sputtering film 312, and the oxidation-reduction reflow method is used as the reflow method. However, another reflow method may alternatively be used.

(Fourth Embodiment)

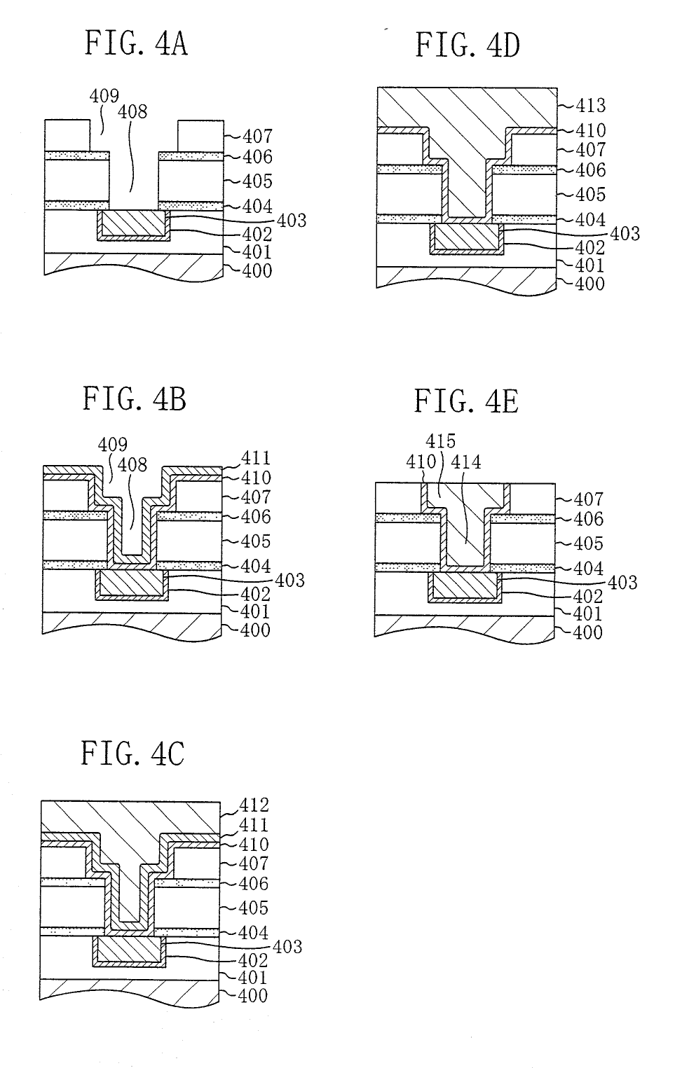

Hereinafter, a semiconductor device and a manufacturing method thereof according to the fourth embodiment of the present invention will be described with reference to FIGS. 4A to 4E.

First, like the step of FIG. 1A in the first embodiment, as shown in FIG. 4A, a first wiring 403 of, e.g., a copper film is embedded in a first insulating film 401 on a semiconductor substrate 400 with a first barrier metal film 402 of, e.g., a TaN film interposed therebetween. Then, a first silicon nitride film 404, a second insulating film 405, a second silicon nitride film 406 and a third insulating film 407 are sequentially deposited on the semiconductor substrate 400. A via hole 408 reaching the first wiring 403 is then formed through the first silicon nitride film 404, second insulating film 405 and second silicon nitride film 406. The via hole 408 has a depth of about 500 nm. A wiring groove 409 reaching the first wiring 403 through the via hole 408 is also formed through the third insulating film 407. The wiring groove 409 has a depth of about 300 nm. The first barrier metal film 402 or the first silicon nitride film 404 prevents the copper atoms of the first wiring 403 from diffusing into the first insulating film 401, the second insulating film 405 or the like due to the thermal processing at about 400° C. (e.g., plasma CVD method) for depositing the second insulating film 405, the second silicon nitride film 406 or the like. In other words, the first barrier metal film 402 or the first silicon nitride film 404 serves as a barrier against diffusion of the copper atoms.

As shown in FIG. 4B, a second barrier metal film 410 of, e.g., a TaN film is then deposited on the semiconductor substrate 400 by, e.g., a sputtering method. The second barrier metal film 410 has a thickness of, e.g., 25 nm. Thereafter, a copper alloy adhesive layer 411 having a thickness of 150 nm is deposited on the second barrier metal film 410 by, e.g., a sputtering method using a copper alloy target of Cu—1% by mass of Al. Thus, the respective bottoms and wall surfaces of the via hole 408 and the wiring groove 409 are covered with the second barrier metal film 410 and the copper alloy adhesive layer 411. Note that the copper alloy adhesive layer 411 contains about 1% by mass of Al.

The semiconductor substrate 400 is then transferred from the sputtering apparatus into a CVD apparatus. At this time, the copper alloy adhesive layer 411 is exposed to the air. Since the copper alloy adhesive layer 411 forms an extremely thin (about several nanometers) aluminum oxide layer (Al₂O₃ film) at its surface, Cu included in the copper alloy adhesive layer 411 will not be oxidized.

Then, as shown in FIG. 4C, a copper CVD film 412 having a thickness of 350 nm is grown on the copper alloy adhesive layer 411 by a CVD method so as to completely fill the via hole 408 and the wiring groove 409. Since Cu included in the copper alloy adhesive layer 411 is not oxidized, adhesion between the second barrier metal film 410 and the copper CVD film 412 will not be degraded, as well as the copper CVD film 412 will not be deposited in a non-uniform manner.

Thereafter, the copper CVD film 412 is thermally processed at, e.g., about 100° C. to about 400° C. in order to grow crystal grains of the copper CVD film 412. As a result, the aluminum atoms included in the copper alloy adhesive layer 411 are diffused into the copper CVD film 412, so that the copper alloy adhesive layer 411 and the copper CVD film 412 are integrated into a wiring copper alloy film 413 containing about 0.3% by mass of aluminum, as shown in FIG. 4D. Note that, instead of thermally processing the copper CVD film 412, the semiconductor substrate 400 may be left at room temperature for about two days. Alternatively, an additional step involving temperature rise (about 100° C. to about 400° C.) may be conducted between the step of forming the copper CVD film 412 and the step of removing the wiring copper alloy film 413 located outside the wiring groove 409 (see FIG. 4E). In such a case, the aforementioned thermal processing may be omitted.

As shown in FIG. 4E, by using, e.g., a CMP method, the second barrier metal film 410 and the wiring copper alloy film 413 located outside the wiring groove 409 are then removed to form a via 414 and a second wiring 415 from the wiring copper alloy film 413. Thus, the first wiring 403 is connected to the second wiring 415 through the via 414.

Note that the copper alloy adhesive layer 411 and the copper CVD film 412 are integrated into the wiring copper alloy film 413 as a result of diffusion of the aluminum atoms in the copper alloy adhesive layer 411 into the copper CVD film 412. Therefore, the aluminum content in the via 414 and the second wiring 415 is increased toward the second barrier metal film 410, that is, toward the first silicon nitride film 404, second insulating film 405, second silicon nitride film 406, third insulating film 407 or first wiring 403.

Although not shown in the figure, a desired multi-layer wiring structure is then formed as necessary by repeatedly conducting the steps of FIGS. 4A to 4E (regarding FIG. 4A, the step of depositing the first silicon nitride film 404 and the following steps).

As has been described above, according to the fourth embodiment, the copper alloy adhesive layer 411 of an Al-containing copper alloy is deposited on the respective bottoms and wall surfaces of the via hole 408 and the wiring groove 409. Thereafter, by using a CVD method, the copper CVD film 412 is formed on the copper alloy adhesive layer 411 so as to completely fill the via hole 408 and the wiring groove 409. Then, the copper alloy adhesive layer 411 and the copper CVD film 412 are integrated into the wiring copper alloy film 413, so that the via 414 and the second wiring 415 are formed from the wiring copper alloy film 413. In other words, an Al-containing copper alloy, i.e., an oxidation-resistant copper alloy, is used as a material of the copper alloy adhesive layer 411, whereby oxidation of Cu included in the copper alloy adhesive layer 411 can be prevented. As a result, degradation in reliability of the via 414 and the second wiring 415 due to the oxidation of Cu can be prevented.

Moreover, according to the fourth embodiment, the wiring copper alloy film 413 that will result in the via 414 and the second wiring 415 is formed from an Al-containing copper alloy, that is, an oxidation-resistant copper alloy that is less susceptible to mechanical deformation than pure copper. Therefore, the via 414 and the second wiring 415 have improved electro-migration resistance or stress migration resistance.

Note that, in the fourth embodiment, an Al-containing copper alloy is used as a material of the copper alloy adhesive layer 411. However, the present invention is not limited to this, and it is preferable to use a copper alloy containing at least one of the elements Al, Si, Ir and Ru. Although Cu—1% by mass of Al is used as the Al-containing copper alloy, the Al content in the copper alloy is not specifically limited.

In the fourth embodiment, pure copper is used as a material of the first wiring 403 or the copper CVD film 412. However, a copper alloy may alternatively be used.

In the fourth embodiment, a TaN film is used as the first barrier metal film 402 or the second barrier metal film 410. However, a Ta film, Ti film, TiN film or the like may alternatively be used.

In the fourth embodiment, an SiO₂ film, an SOG film, a CVD film including C and having a low dielectric constant, or the like may be used as the first insulating film 401, second insulating film 405 or third insulating film 407.

A dual damascene method in which the via hole 408 and the wiring groove 409 are simultaneously filled with a conductive film is used in the fourth embodiment. Alternatively, the via hole 408 and the wiring groove 409 may be separately formed and separately filled with a conductive film.

In the fourth embodiment, the copper alloy adhesive layer 411 is deposited after deposition of the second barrier metal film 410. However, the copper alloy adhesive layer 411 may alternatively be deposited without deposition of the second barrier metal film 410. In this case, it is preferable to nitride the surface of the second insulating film 405 or the surface of the third insulating film 407 before deposition of the copper alloy adhesive layer 411 by exposing the semiconductor substrate 400 to nitrogen plasma or ammonia plasma.

In the fourth embodiment, the via hole 408 and the wiring groove 409 are filled with the copper CVD film 412. However, it is also possible to first fill the via hole 408 with the copper CVD film 412 and then fill the wiring groove 409 with a copper plating film grown on the copper CVD film 412 by, e.g., an electroplating method.

(Fifth Embodiment)

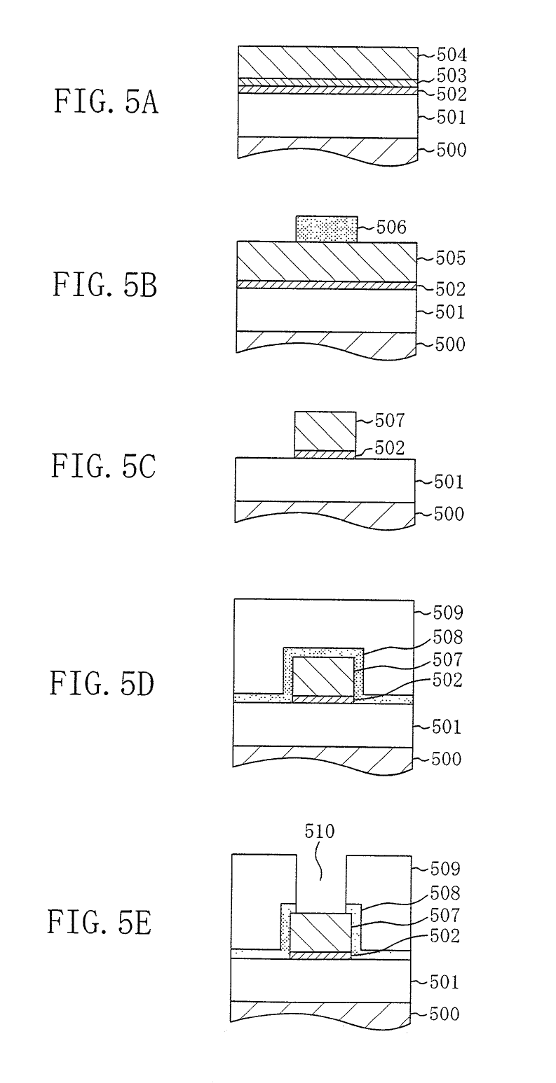

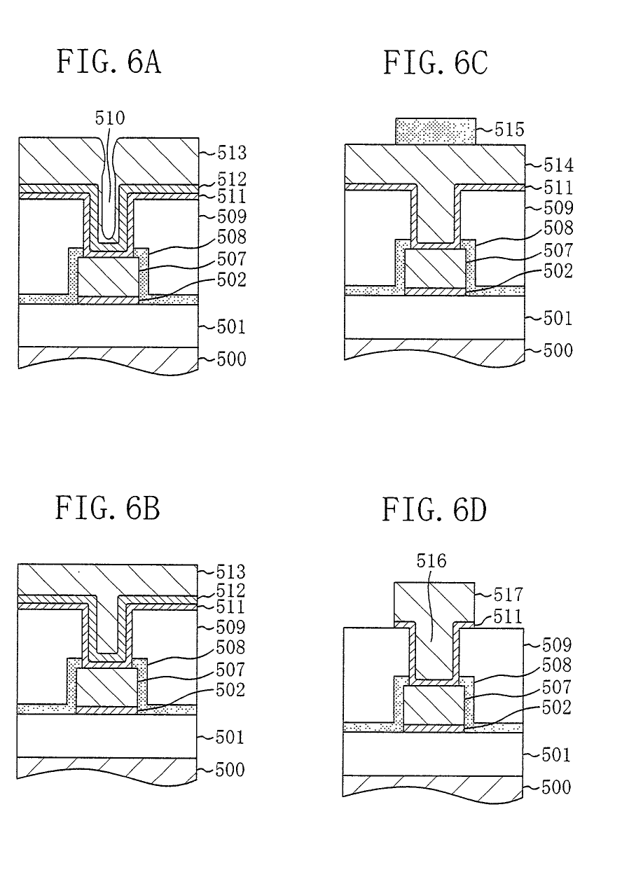

Hereinafter, a semiconductor device and a manufacturing method thereof according to the fifth embodiment of the present invention will be described with reference to FIGS. 5A to SE and FIGS. 6A to 6D.

First, as shown in FIG. 5A, a first barrier metal film 502 of, e.g., a TaN film is deposited on a first insulating film 501 on a semiconductor substrate 500 by, e.g., a sputtering method. The first barrier metal film 502 has a thickness of 10 nm. Thereafter, a copper alloy seed layer 503 having a thickness of 100 nm is deposited on the first barrier metal film 502 by, e.g., a sputtering method using a copper alloy target of Cu—1% by mass of Al. Note that the copper alloy seed layer 503 contains about 1% by mass of Al.

The semiconductor substrate 500 is then transferred from the sputtering apparatus into a plating apparatus. At this time, the copper alloy seed layer 503 is exposed to the air. Since the copper alloy seed layer 503 forms an extremely thin (about several nanometers) aluminum oxide layer (Al₂O₃ film) at its surface, Cu included in the copper alloy seed layer 503 will not be oxidized. Then, as shown in FIG. 5A, a copper plating film 504 having a thickness of 500 nm is grown on the copper alloy seed layer 503 by an electroplating method. More specifically, with the semiconductor substrate 500 being immersed in a plating solution including CuSO₄, H₂SO₄ and the like, the electroplating method is conducted such that the semiconductor substrate 500 has a negative potential. Note that, although not shown in the figure, in the case where the first insulating film 501 has a recess such as a contact hole or via hole, the recess is filled with the copper plating film 504 with the first barrier metal film 502 and the copper alloy seed layer 503 interposed therebetween.

Thereafter, the semiconductor substrate 500 is removed from the plating apparatus, and the copper plating film 504 is thermally processed at, e.g., about 100° C. to about 400° C. in order to grow crystal grains of the copper plating film 504. As a result, the aluminum atoms included in the copper alloy seed layer 503 are diffused into the copper plating film 504, so that the copper alloy seed layer 503 and the copper plating film 504 are integrated into a first wiring copper alloy film 505, as shown in FIG. 5B. Note that, instead of thermally processing the copper plating film 504, the semiconductor substrate 500 may be left at room temperature for about two days. Alternatively, an additional step involving temperature rise (about 100° C. to about 400° C.) may be conducted between the step of forming the copper plating film 504 and the step of etching the first wiring copper alloy film 505 (see FIG. 5C). In such a case, the aforementioned thermal processing may be omitted.

As shown in FIG. 5B, a first resist pattern 506 is then formed on the first wiring copper alloy film 505 so as to cover a first wiring formation region.

As shown in FIG. 5C, by using the first resist pattern 506 as a mask, the first wiring copper alloy film 505 and the first barrier metal film 502 are sequentially etched to form a first wiring 507 on the first insulating film 501 with the first barrier metal film 502 interposed therebetween.

Note that the copper alloy seed layer 503 and the copper plating film 504 are integrated into the first wiring copper alloy film 505 as a result of diffusion of the aluminum atoms in the copper alloy seed layer 503 into the copper plating film 504. Therefore, the aluminum content in the first wiring 507 is increased toward the first barrier metal film 502, that is, toward the first insulating film 501.

Thereafter, as shown in FIG. 5D, a silicon nitride film 508 and a second insulating film 509 are sequentially deposited on the first insulating film 507 and the first insulating film 501. As a result, the top and side surfaces of the first wiring 507 are covered with the second insulating film 509 with the silicon nitride film 508 interposed therebetween. The first barrier metal film 502 or the silicon nitride film 508 prevents the copper atoms of the first wiring 507 from diffusing into the first insulating film 501, the second insulating film 509 or the like due to the thermal processing at about 400° C. (e.g., plasma CVD method) for depositing the second insulating film 509 or the like. In other words, the first barrier metal film 502 or the silicon nitride film 508 serves as a barrier against diffusion of the copper atoms.

As shown in FIG. 5E, a via hole 510 reaching the first wiring 507 is then formed through the silicon nitride film 508 and the second insulating film 509. The via hole 510 has a depth of about 500 nm.

As shown in FIG. 6A, a second barrier metal film 511 of, e.g., a TaN film is then deposited on the second insulating film 509 including the via hole 510 by, e.g., a sputtering method. The second barrier metal film 511 has a thickness of, e.g., 25 nm. Thereafter, a copper alloy wetting layer 512 having a thickness of 150 nm is deposited on the second barrier metal film 511 by, e.g., a sputtering method using a copper alloy target of Cu—1% by mass of Al. Thus, the bottom and wall surface of the via hole 510 are covered with the second barrier metal film 511 and the copper alloy wetting layer 512. Note that the copper alloy wetting layer 512 contains about 1% by mass of Al.

Thereafter, a copper sputtering film 513 having a thickness of 600 nm is deposited on the copper alloy wetting layer 512 by using, e.g., a sputtering method. At this time, the via hole 510 cannot completely be filled with the copper sputtering film 513 due to the directivity of the sputtering method, as shown in FIG. 6A.

As shown in FIG. 6B, the copper sputtering film 513 is then repeatedly oxidized and reduced in an oxidative-reducing atmosphere by using, e.g., an oxidation-reduction reflow method. The resultant reaction heat causes the copper sputtering film 513 to flow, thereby completely filling the via hole 510. Note that, upon oxidizing the copper sputtering film 513, the copper alloy wetting layer 512 is also oxidized simultaneously. However, since the copper alloy wetting layer 512 forms an extremely thin (about several nanometers) aluminum oxide layer (A1₂O₃ film) at its surface, Cu included in the copper alloy wetting layer 512 will not be oxidized. As a result, degradation in the reflow property of the copper sputtering film 513 on the copper alloy wetting layer 512 can be prevented.

Thereafter, the copper sputtering film 513 is thermally processed at, e.g., about 100° C. to about 400° C. in order to grow crystal grains of the copper sputtering film 513. As a result, the aluminum atoms included in the copper alloy wetting layer 512 are diffused into the copper sputtering film 513, so that the copper alloy wetting layer 512 and the copper sputtering film 513 are integrated into a second wiring copper alloy film 514 containing about 0.3% by mass of aluminum, as shown in FIG. 6C. Note that, instead of thermally processing the copper sputtering film 513, the semiconductor substrate 500 may be left at room temperature for about two days. Alternatively, an additional step involving temperature rise (about 100° C. to about 400° C.) may be conducted between the step of forming the copper sputtering film 513 and the step of etching the second wiring copper alloy film 514 (see FIG. 6D). In such a case, the aforementioned thermal processing may be omitted.

As shown in FIG. 6C, a second resist pattern 515 is then formed on the second wiring copper alloy film 514 so as to cover a second wiring formation region. By using the second resist pattern 515 as a mask, the second wiring copper alloy film 514 and the second barrier metal film 511 are sequentially etched to form a via 516 and a second wiring 517 from the second wiring copper alloy film 514, as shown in FIG. 6D. Thus, the first wiring 507 is connected to the second wiring 517 through the via 516.

Note that the copper alloy wetting layer 512 and the copper sputtering film 513 are integrated into the second wiring copper alloy film 514 as a result of diffusion of the aluminum atoms in the copper alloy wetting layer 512 into the copper sputtering film 513. Therefore, the aluminum content in the via 516 and the second wiring 517 is increased toward the second barrier metal film 511, that is, toward the silicon nitride film 508, second insulating film 509 or first wiring 507.

Although not shown in the figure, a desired multi-layer wiring structure is then formed as necessary by repeatedly conducting the steps of FIGS. 5D and 5E and FIGS. 6A to 6D.

As has been described above, according to the fifth embodiment, the copper alloy seed layer 503 of an Al-containing copper alloy is deposited on the first insulating film 501. Thereafter, by using an electroplating method, the copper plating film 504 is grown on the copper alloy seed layer 503. Then, the copper alloy seed layer 503 and the copper plating film 504 are integrated into the first wiring copper alloy film 505. The first wiring copper alloy film 505 is etched to form the first wiring 507. In other words, an Al-containing copper alloy, i.e., an oxidation-resistant copper alloy, is used as a material of the copper alloy seed layer 503, whereby oxidation of Cu included in the copper alloy seed layer 503 can be prevented. As a result, degradation in reliability of the first wiring 507 due to the oxidation of Cu can be prevented.

Moreover, according to the fifth embodiment, the first wiring copper alloy film 505 that will result in the first wiring 507 is formed from an Al-containing copper alloy, that is, an oxidation-resistant copper alloy that is less susceptible to mechanical deformation than pure copper. Therefore, the first wiring 507 has improved electro-migration resistance or stress migration resistance.

According to the fifth embodiment, the copper alloy wetting layer 512 of an Al-containing copper alloy is deposited on the second insulating film 509 including the via hole 510. Thereafter, by using the sputtering and reflow methods, the copper sputtering film 513 is formed on the copper alloy wetting layer 512 so as to completely fill the via hole 510. Then, the copper alloy wetting layer 512 and the copper sputtering film 513 are integrated into the second wiring copper alloy film 514. The second wiring copper alloy film 514 is etched to form the via 516 and the second wiring 517. In other words, an Al-containing copper alloy, i.e., an oxidation-resistant copper alloy, is used as a material of the copper alloy wetting layer 512, whereby oxidation of Cu included in the copper alloy wetting layer 512 can be prevented. As a result, degradation in reliability of the via 516 and the second wiring 517 due to the oxidation of Cu can be prevented.

Moreover, according to the fifth embodiment, the second wiring copper alloy film 514 that will result in the via 516 and the second wiring 517 is formed from an Al-containing copper alloy, that is, an oxidation-resistant copper alloy that is less susceptible to mechanical deformation than pure copper. Therefore, the via 516 and the second wiring 517 have improved electro-migration resistance or stress migration resistance.

Note that, in the fifth embodiment, an Al-containing copper alloy is used as a material of the copper alloy seed layer 503 or the copper alloy wetting layer 512. However, the present invention is not limited to this, and it is preferable to use a copper alloy containing at least one of the elements Al, Si, Ir and Ru. Although Cu—1% by mass of Al is used as the Al-containing copper alloy, the Al content in the copper alloy is not specifically limited.

In the fifth embodiment, pure copper is used as a material of the copper plating film 504 or the copper sputtering film 513. However, a copper alloy may alternatively be used.

In the fifth embodiment, a TaN film is used as the first barrier metal film 502 or the second barrier metal film 511. However, a Ta film, Ti film, TiN film or the like may alternatively be used.

In the fifth embodiment, an SiO₂ film, an SOG film, a CVD film including C and having a low dielectric constant, or the like may be used as the first insulating film 501 or the second insulating film 509.

In the fifth embodiment, it is preferable to deposit the copper alloy seed layer 503 with (111) orientation with respect to the top surface of the first barrier metal film 502, i.e., the top surface of the first insulating film 501, in the step of depositing the copper alloy seed layer 503 (see FIG. 5A). As a result, the copper plating film 504 on the copper alloy seed layer 503 is also more likely to be grown with (111) orientation with respect to the top surface of the first insulating film 501. Accordingly, the first wiring 507 formed from the first wiring copper alloy film 505, i.e., from the integrated film of the copper alloy seed layer 503 and the copper plating film 504, has improved electro-migration resistance.

In the fifth embodiment, it is preferable to improve the (111) orientation of the copper alloy seed layer 503 by, e.g., a thermal processing after deposition of the copper alloy seed layer 503. This also improves the (111) orientation of the copper plating film 504, so that the first wiring 507 has further improved electro-migration resistance.

In the fifth embodiment, the copper alloy seed layer 503 is deposited after deposition of the first barrier metal film 502. However, the copper alloy seed layer 503 may alternatively be deposited without deposition of the first barrier metal film 502. In this case, it is preferable to nitride the surface of the first insulating film 501 before deposition of the copper alloy seed layer 503 by exposing the semiconductor substrate 500 to nitrogen plasma or ammonia plasma.

In the fifth embodiment, the copper alloy wetting layer 512 is deposited after deposition of the second barrier metal film 511. However, the copper alloy wetting layer 512 may alternatively be deposited without deposition of the second barrier metal film 511. In this case, it is preferable to nitride the surface of the second insulating film 509 before deposition of the copper alloy wetting layer 512 by exposing the semiconductor substrate 500 to nitrogen plasma or ammonia plasma.

In the fifth embodiment, the electroplating method is used to form the first wiring 507. However, combination of sputtering and reflow methods, a CVD method or the like may alternatively be used.

In the fifth embodiment, the combination of sputtering and reflow methods is used to form the second wiring 517. However, an electroplating method, a CVD method or the like may alternatively be used. In the combination of sputtering and reflow methods, the oxidation-reduction reflow method is used as the reflow method in the fifth embodiment. However, another reflow method may alternatively be used.

What is claimed is:

1. A semiconductor device, comprising:
an insulating film formed on a substrate; and
an embedded wiring formed in the insulating film, wherein
the embedded wiring is formed from a copper alloy containing at least one of elements Al, Si, Ir and Ru, and a content of the element in the embedded wiring is increased toward the insulating film.

2. A semiconductor device, comprising:
an insulating film formed on a substrate; and
a wiring formed on the insulating film, wherein
the wiring is formed from a copper alloy containing at least one of elements Al, Si, Ir and Ru, and a content of the element in the wiring is increased toward the insulating film.

3. A method for manufacturing a semiconductor device, comprising the steps of:
forming a recess in an insulating film on a substrate;
depositing a first conductive film on a bottom and wall surface of the recess, the first conductive film being formed from a first copper alloy having oxidation resistance;
growing a second conductive film on the first conductive film by an electroplating method so as to completely fill the recess, the second conductive film being formed from copper or a second copper alloy; and
integrating the first and second conductive films into a third conductive film so as to form an embedded wiring of the third conductive film.

4. The method according to claim 3, wherein the step of depositing the first conductive film includes the step of depositing the first conductive film with (111) orientation with respect to the bottom of the recess.

5. The method according to claim 3, wherein the first copper alloy contains at least one of elements Al, Si, Ir and Ru.

6. A method for manufacturing a semiconductor device, comprising the steps of:
depositing a first conductive film on an insulating film on a substrate, the first conductive film being formed from a first copper alloy having oxidation resistance;
growing a second conductive film on the first conductive film by an electroplating method, the second conductive film being formed from copper or a second copper alloy;
integrating the first and second conductive films into a third conductive film; and
forming a wiring of the third conductive film by etching the third conductive film using a mask pattern covering a wiring formation region.

7. The method according to claim 6, wherein the step of depositing the first conductive film includes the step of depositing the first conductive film with (111) orientation with respect to a top surface of the insulating film.

8. The method according to claim 6, wherein the first copper alloy contains at least one of elements Al, Si, Ir and Ru.

9. A method for manufacturing a semiconductor device, comprising the steps of:
forming a recess in an insulating film on a substrate;
depositing a first conductive film on a bottom and wall surface of the recess, the first conductive film being formed from a first copper alloy having oxidation resistance;
forming a second conductive film on the first conductive film so as to completely fill the recess, the second conductive film being formed from copper or a second copper alloy; and
integrating the first and second conductive films into a third conductive film so as to form an embedded wiring of the third conductive film.

10. The method according to claim 9, wherein the step of forming the second conductive film includes the step of causing the second conductive film to flow by a thermal processing after deposition of the second conductive film by a sputtering method.

11. The method according to claim 9, wherein the step of forming the second conductive film includes the step of depositing the second conductive film by a CVD (chemical vapor deposition) method.

12. The method according to claim 9, wherein the first copper alloy contains at least one of elements Al, Si, Ir and Ru.

13. A method for manufacturing a semiconductor device, comprising the steps of:
depositing a first conductive film on an insulating film on a substrate, the first conductive film being formed from a first copper alloy having oxidation resistance;
forming a second conductive film on the first conductive film, the second conductive film being formed from copper or a second copper alloy;
integrating the first and second conductive films into a third conductive film; and
forming a wiring of the third conductive film by etching the third conductive film using a mask pattern covering a wiring formation region.

14. The method according to claim 13, wherein the step of forming the second conductive film includes the step of causing the second conductive film to flow by a thermal processing after deposition of the second conductive film by a sputtering method.

15. The method according to claim 13, wherein the step of forming the second conductive film includes the step of depositing the second conductive film by a CVD method.

16. The method according to claim 13, wherein the first copper alloy contains at least one of elements Al, Si, Ir and Ru.
